(19) United States
(12) Patent Application Publication
(10) Pub. No.: US 2020/0403176 A1
(43) Pub. Date: Dec. 24, 2020

(54) DISPLAY DEVICE

(71) Applicant: Japan Display Inc., Tokyo (JP)

(72) Inventor: Masakazu GUNJI, Tokyo (JP)

(21) Appl. No.: 17/012,267

(22) Filed: Sep. 4, 2020

Related U.S. Application Data
(63) Continuation of application No. PCT/JP2019/001463, filed on Jan. 18, 2019.

(30) Foreign Application Priority Data
Mar. 7, 2018 (JP) 2018-040376

(51) Int. Cl. H01L 51/50; H01L 27/32

(52) U.S. Cl. CPC H01L 51/5056; H01L 51/5092; H01L 27/326; H01L 27/3276; H01L 27/3246

(57) ABSTRACT

A display device includes a substrate, a plurality of pixel electrodes apart from each other which are provided above the substrate, a counter electrode disposed above the plurality of pixel electrodes, an organic EL layer interposed between the plurality of pixel electrodes and the counter electrode, an intermediate electrode disposed between the pixel electrodes adjacent to each other in plan view, and an insulating film provided between the intermediate electrode and the organic EL layer.

### CROSS-REFERENCE TO RELATED APPLICATION

The present application is continuation of International Application No. PCT/JP2019/001463 filed on Jan. 18, 2019, which claims priority from Japanese Application No. JP 2018-040376 filed on Mar. 7, 2018. The contents of these applications are hereby incorporated by reference into this application.

### BACKGROUND

### 1. Field of the Invention

The present invention relates to a display device.

### 2. Description of the Related Art

Recently, devices, such as smartphones, using organic EL display devices have increased. The organic EL display device includes a lower electrode, an organic EL layer, and an upper electrode. The lower electrode and the organic EL layer are provided for each pixel, and the upper electrode is commonly provided for a plurality of pixels. The organic EL layer includes a hole injection layer, a hole transport layer, a light emitting layer, an electron transport layer, and an electron injection layer.

JP 2016-85913 A discloses an organic EL display device including an organic EL layer including a hole injection layer, a hole transport layer, a light emitting layer, an electron transport layer, and an electron injection layer. In the organic EL display device, an electrode which is in contact with the organic EL layer is provided on a bank.

In an organic EL display device, when an organic EL layer that covers a plurality of pixels is provided, a phenomenon in which a current leaks from a pixel electrode of a certain pixel to the light emitting layer of the adjacent pixel, and thus the adjacent pixel emits light may occur. When such a phenomenon occurs, for example, a problem (described to as “electrical color mixing” below) that a display color is different from an intended color occurs.

### SUMMARY OF THE INVENTION

The present invention has been made in view of the above problem, and an object thereof is to provide a display device capable of suppressing an occurrence of a phenomenon in which an adjacent pixel emits light unintentionally when one pixel emits light.

According to the present invention, a display device includes a substrate, a plurality of pixel electrodes apart from each other which are provided above the substrate, a counter electrode disposed above the plurality of pixel electrodes, an organic EL layer interposed between the plurality of pixel electrodes and the counter electrode, an intermediate electrode disposed between the pixel electrodes adjacent to each other in plan view, and an insulating film provided between the intermediate electrode and the organic EL layer.

According to the present invention, it is possible to suppress an occurrence of a phenomenon in which an adjacent pixel emits light unintentionally when one pixel emits light.

### BRIEF DESCRIPTION OF THE DRAWINGS

FIG. 1 is a plan view illustrating an organic EL display device according to an embodiment;

FIG. 2 is a partial plan view schematically illustrating an example of the organic EL display device;

FIG. 3 is a sectional view illustrating the organic EL display device taken along line III-III illustrated in FIG. 2;

FIG. 4 is a sectional view illustrating a comparative example of the organic EL display device;

FIG. 5 is a sectional view illustrating another example of the organic EL display device;

FIG. 6 is a sectional view illustrating still another example of the organic EL display device;

FIG. 7 is a partial plan view schematically illustrating still another example of the organic EL display device;

FIG. 8 is a partial plan view schematically illustrating still another example of the organic EL display device;

FIG. 9 is a partial plan view schematically illustrating still another example of the organic EL display device;

FIG. 10 is a sectional view illustrating the organic EL display device taken along line X-X illustrated in FIG. 9; and

FIG. 11 is a sectional view illustrating still another example of the organic EL display device.

### DETAILED DESCRIPTION OF THE INVENTION

Hereinafter, an embodiment of the present invention will be described with reference to the drawings. The present invention can be carried out in various forms without departing from the gist of the invention, and should not be construed as being limited to the description of the embodiment described below.

In order to make the description clearer, the drawings may be schematically illustrated in terms of the width, thickness, shape, and the like of each unit as compared with the actual ones, but they are merely examples and are not intended to limit the interpretation of the present invention. In this specification and each drawing, elements having similar functions to those described previously with reference to the drawings are denoted by the same reference signs, and the repetitive description thereof may be omitted.

In the detailed description of the present invention, when defining the positional relationship between a certain component and another component, the terms “above” and “below” include not only the case where located directly above or below the certain component, but also the case where other components are further interposed therebetween unless otherwise specified.

### Embodiment

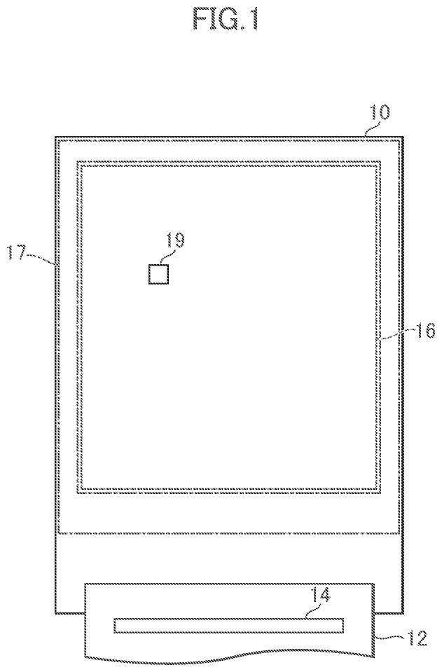

FIG. 1 is a plan view illustrating an organic electroluminescence (EL) display device according to an embodiment of the present invention. The organic EL display device includes a substrate 10, a flexible printed circuit board 12, an integrated circuit package 14 disposed on the flexible printed circuit board 12. In the embodiment, the organic EL display device is a bendable sheet display or a flexible display. The organic EL display device may be a non-flexible display.

The substrate 10 includes a display region 16 and a peripheral region 17 surrounding the display region 16. The peripheral region 17 is outside the display region 16. A plurality of pixels 19 are disposed in the display region 16. For example, the organic EL display device is configured to form the full-color pixel 19 by combining unit pixels (sub-pixels) of a plurality of colors including red, green, and blue and to display a full-color image. The unit pixel has a light emitting region. The pixel 19 may be configured by four or more unit pixels or two unit pixels. The flexible printed circuit board 12 is connected to one end of the substrate 10. A portion of a drive circuit that drives a pixel circuit in the unit pixel is mounted in the integrated circuit package 14. A portion of the drive circuit is also disposed in the peripheral region 17 on the substrate 10.

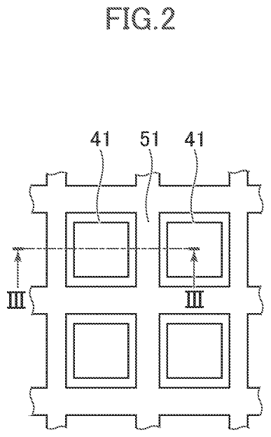

FIG. 2 is a partial plan view schematically illustrating an example of the organic EL display device. FIG. 2 mainly illustrates a planar disposition of a pixel electrode 41 and an intermediate electrode 51 in the organic EL display device. Each pixel electrode 41 corresponds to the unit pixel. In plan view, the intermediate electrode 51 is disposed between the pixel electrodes 41 adjacent to each other. In the example in FIG. 2, the intermediate electrode 51 surrounds the pixel electrode 41 without a break.

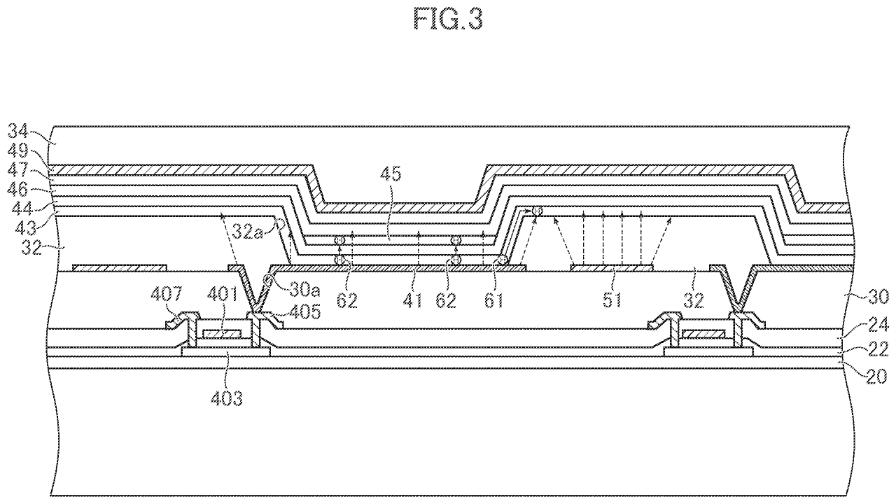

FIG. 3 is a sectional view illustrating the organic EL display device taken along line III-III illustrated in FIG. 2. The substrate (array substrate) 10 has flexibility. The material of the substrate 10 is polyimide, but another resin material may be used so long as the resin material is a base material having sufficient flexibility to form a sheet display or a flexible display. Ina case of a display device other than the sheet display or the flexible display, the material of the substrate 10 may be glass.

A base layer 20 containing silicon oxide and silicon nitride is provided on the substrate 10. The base layer 20 may have a three-layer stacked structure including a first base layer, a second base layer, and a third base layer. For example, the first base layer is a silicon oxide layer for improving adhesion to the substrate 10. The second base layer is a silicon nitride layer that blocks moisture and impurities from the outside. The third base layer blocks hydrogen atoms contained in the second base layer not to be diffused toward an upper thin film transistor.

A plurality of thin film transistors are formed on the base layer 20. Each of the thin film transistors includes a gate electrode 401, a semiconductor film 403, a source electrode 405, and a drain electrode 407. The semiconductor film 403 is provided on the base layer 20. The semiconductor film 403 may be made of polysilicon, or may be a transparent amorphous oxide semiconductor (TAOS). A gate insulating layer 22 containing silicon oxide is provided on the semiconductor film 403. A first conductive layer including the gate electrode 401 that overlaps the semiconductor film 403 in plan view is provided on the gate insulating layer 22. The first conductive layer is formed of MoW, for example. An interlayer insulating layer 24 containing silicon nitride and silicon oxide is provided on the gate electrode 401. The gate insulating layer 22 and the interlayer insulating layer 24 may be formed of other materials having insulating properties.

A second conductive layer including the source electrode 405 and the drain electrode 407 is provided on the interlayer insulating layer 24. The source electrode 405 and the drain electrode 407 are connected to a wiring (for example, pixel electrode 41) forming the pixel circuit. The second conductive layer has a three-layer stacked structure made of Ti, Al, and Ti, for example.

A planarizing film 30 is provided to cover the source electrode 405 and the drain electrode 407. Organic materials such as photosensitive acrylic are frequently used as the planarizing film 30. The organic material is excellent in surface flatness, compared to an inorganic insulating material formed by chemical vapor deposition (CVD) or the like.

The planarizing film 30 has an opening 30a for exposing the source electrode 405. The pixel electrode 41 is provided to be electrically connected to the source electrode 405 through the opening 30a. The pixel electrode 41 may have a three-layer stacked structure including an indium zinc oxide (IZO) film, an Ag film, and an IZO film, for example. The pixel electrode 41 extends laterally from the upper end of the opening 30a. The drain electrode 407, instead of the source electrode 405, may be connected to the pixel electrode 41.

The intermediate electrode 51 is provided between the pixel electrodes 41 adjacent to each other in plan view, in the same layer as the layer for the pixel electrode 41. A potential higher than a potential to be supplied to the pixel electrode 41 is supplied to the intermediate electrode 51. The pixel electrode 41 may be formed on the planarizing film 30 and under a bank 32 and be formed by a process different from a process for the pixel electrode 41.

The bank 32 is formed in a layer on the planarizing film 30 or the layer for the pixel electrode 41. The bank 32 covers the opening 30a. The bank 32 is formed of, for example, photosensitive acrylic having an insulating property, similar to the planarizing film 30. The bank 32 is provided between unit pixels adjacent to each other. The bank 32 includes an opening 32a corresponding to the unit pixel. A side surface of the opening 32a has a tapered shape. The pixel electrode 41 is exposed from the bank 32, on the bottom of the opening 32a. Thus, the bank 32 partition a plurality of pixels.

As an organic EL layer (simply also referred to as an organic layer), a hole injection layer 43, a hole transport layer 44, a light emitting layer 45, an electron transport layer 46, and an electron injection layer 47 are provided on the pixel electrode 41 in order. Here, the light emitting layer 45 is disposed in the opening 32a. The hole injection layer 43, the hole transport layer 44, the electron transport layer 46, and the electron injection layer 47 are continuously formed from the inside of the opening 32a of the bank 32 to the upside of the bank 32. The intermediate electrode 51 and the organic EL layer, in particular, the hole injection layer 43 are insulated from each other by the bank 32.

In the light emitting layer 45, electrons and holes as carriers are injected, and light is emitted. From a different viewpoint, the light emitting layer 45 emits light by a current flowing between the pixel electrode 41 and a counter electrode 49. The light emitting layer 45 formed on the pixel electrode 41 in the opening 32a forms a light emitting region of the unit pixel corresponding to the pixel electrode 41 and the opening 32a.

The hole injection layer 43 and the hole transport layer 44 are layers for accelerating injection of holes as the carriers into the light emitting layer 45. The electron injection layer 47 and the electron transport layer 46 are layers for accelerating injection of electrons as carriers into the light emitting layer 45.

Each of the hole injection layer 43, the hole transport layer 44, the light emitting layer 45, the electron transport layer 46, and the electron injection layer 47 may be formed by vapor deposition of the corresponding material. Here, regarding the light emitting layer 45, the material may be deposited in the opening 32a by using a mask. The above layers maybe formed using coating instead of vapor deposition.

The counter electrode 49 is provided on the electron injection layer 47. For example, the counter electrode 49 may be an Mg layer and an Ag layer formed as a thin film allowing light emitted from the organic EL layer to be transmitted through the Mg layer and the Ag layer, or may be formed of ITO. The counter electrode 49 is also provided on the bank 32. The counter electrode 49 is electrically connected to a wiring for supplying a predetermined potential (for example, ground potential).

A sealing layer 34 is provided on the counter electrode 49. The sealing layer 34 prevents permeation of moisture from the outside into the organic EL layer. The sealing layer 34 has a stacked structure including a silicon nitride film, an organic resin layer, and a silicon nitride film, for example.

A cover glass, a touch panel substrate or the like may be provided on the sealing layer 34. In this case, a space between the sealing layer 34, and the cover glass or the touch panel substrate may be filled with a filler such as resin. A counter substrate using a base material having flexibility, such as polyimide, may be disposed on the sealing layer 34.

Here, an output potential corresponding to a gray level for the unit pixel is supplied to the pixel electrode 41 from the source electrode 405 in the thin film transistor. In the configuration illustrated in FIG. 3, the output potential to be supplied to the pixel electrode 41 is higher than a potential to be supplied to the counter electrode 49. By the potentials supplied to the pixel electrode 41 and the counter electrode 49, an electric field from the pixel electrode 41 toward the counter electrode 49 is generated. Holes 61 and 62 are generated in the hole injection layer 43 which is in contact with the pixel electrode 41, by such an electric field, and the hole 62 moves into the light emitting layer 45. An electron is generated in a region, above the pixel electrode 41, in the electron injection layer 47 in contact with the counter electrode 49. The electron moves into the light emitting layer 45, and is combined with the hole 62 in the light emitting layer 45. Thus, the light emitting layer 45 emits light.

At the end of the pixel electrode 41, the direction of the electric field is inclined to the outside of the pixel electrode 41. Thus, the hole 61 generated in the vicinity of the inner peripheral wall of the opening 32a in the hole injection layer 43 moves onto the bank 32 along the electric field. Since the potential higher than the potential supplied to the pixel electrode 41 is supplied to the intermediate electrode 51, an electric field from the intermediate electrode 51 toward the pixel electrode 41 in plan view is generated in the vicinity of the intermediate electrode 51 in the hole injection layer 43. Therefore, it is not possible that the hole 61 reaches directly above the intermediate electrode 51. Thus, it is possible to prevent an occurrence of a situation in which the hole 61 reaches the light emitting layer 45 on the adjacent pixel electrode 41.

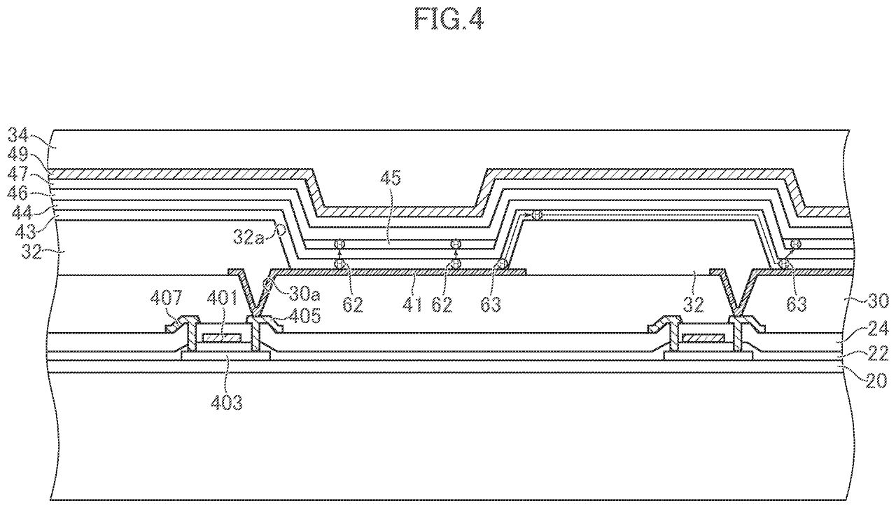

When there is no intermediate electrode 51, the hole 61 generated in a certain pixel electrode 41 may reach the light emitting layer 45 on the adjacent pixel electrode 41. FIG. 4 is a sectional view illustrating a comparative example of the organic EL display device. In the example in FIG. 4, the intermediate electrode 51 is not provided.

With the positive potential supplied to the pixel electrode 41, most of holes 62 among carriers generated in the hole injection layer 43 are combined with electrons in the light emitting layer 45 to disappear. Thus, the light emitting layer 45 emits light. When a potential difference occurs between a certain pixel electrode 41 and the adjacent pixel electrode 41, an electric field that moves some holes 63 is generated by the potential difference. With the generated electric field, such some holes 63 pass by a space on the bank 32 in the hole injection layer 43 and then reach the light emitting layer 45 on the adjacent pixel electrode 41. Therefore, if light is emitted from the light emitting layer 45 on a certain pixel electrode 41, light is also slightly emitted from the light emitting layer on the adjacent pixel electrode 41. On the contrary, in the configuration illustrated in FIG. 3, an occurrence of a situation in which the hole 61 crosses over the intermediate electrode 51 and moves is suppressed. Thus, it is possible to prevent an occurrence of slight light emission in the adjacent light emitting layer 45.

In addition, in the configuration illustrated in FIG. 3, the pixel electrode 41 and the intermediate electrode 51 can be formed by the same process. Thus, it is possible to prevent an increase in a manufacturing process.

Here, as the organic EL layer on the pixel electrode 41, the electron injection layer 47, the electron transport layer 46, the light emitting layer 45, the hole transport layer 44, and the hole injection layer 43 may be provided in order. The pixel electrode 41 may supply electrons as carriers. In this case, a potential lower than the potential of the counter electrode 49 is supplied to the pixel electrode 41. A potential lower than the potential of the pixel electrode 41 is applied to the intermediate electrode 51. Thus, it is possible to prevent an occurrence of a situation in which the light emitting layer 45 on the adjacent pixel electrode 41 emits light by electrons as carriers generated in the vicinity of the pixel electrode 41.

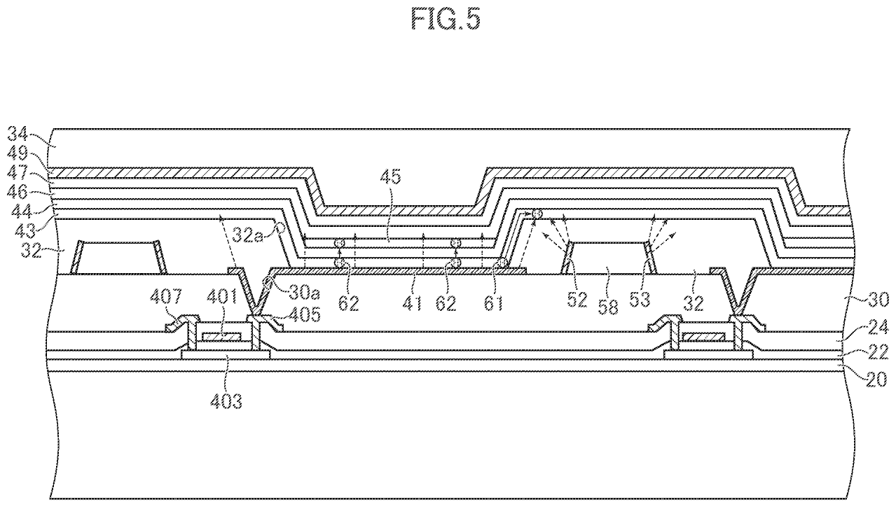

The disposition of the intermediate electrode 51 is not limited to the disposition illustrated in FIG. 3. FIG. 5 is a sectional view illustrating another example of the organic EL display device and is a view corresponding to FIG. 3. In the example in FIG. 5, an internal protrusion 58 is provided between the bank 32 and the planarizing film 30 and between the pixel electrodes 41 adjacent to each other. The cross section of the internal protrusion 58 is trapezoidal, and the side surface is tapered. Intermediate electrodes 52 and 53 are provided to cover the side surface of the internal protrusion 58.

In the example in FIG. 5, with the internal protrusion 58, it is possible to reduce a distance between the hole injection layer 43 and the intermediate electrodes 52 and 53. Thus, it is possible to enhance an electric field applied from the intermediate electrodes 52 and 53 to the hole injection layer 43 and to more reliably prevent the occurrence of slight light emission in the adjacent light emitting layer 45. In the manufacturing process, formation of the planarizing film 30, formation of the internal protrusion 58, formation of the pixel electrode 41 and the intermediate electrodes 52 and 53, and formation of the bank 32 are sequentially performed, and thus it is possible to suppress the increase in the manufacturing process to the minimum.

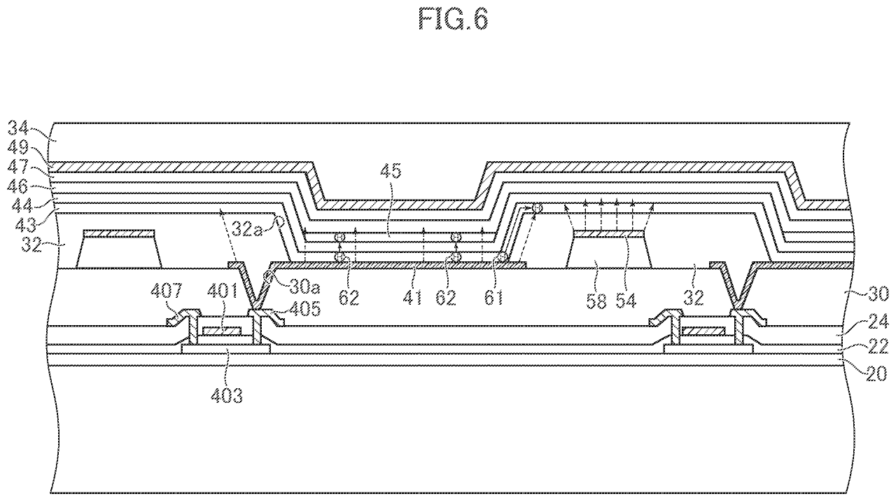

FIG. 6 is a sectional view illustrating still another example of the organic EL display device and is a view corresponding to FIG. 3. Similar to the example in FIG. 5, in the example in FIG. 6, the internal protrusion 58 is provided. However, an intermediate electrode 54 is provided on the upper surface of the internal protrusion 58. In the example in FIG. 6, with the internal protrusion 58, it is also possible to reduce a distance between the hole injection layer 43 and the intermediate electrode 54. Thus, it is possible to enhance an electric field applied from the intermediate electrode 54 to the hole injection layer 43 and to prevent the occurrence of slight light emission in the adjacent light emitting layer 45 more reliably. The intermediate electrode 54 may be provided not only on the upper surface of the internal protrusion 58, but also on the side surface.

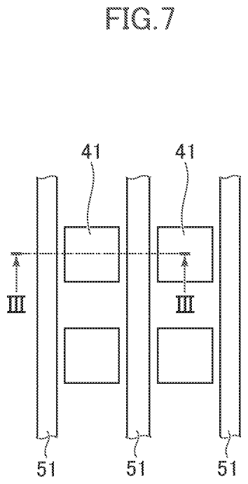

The intermediate electrode 51 may not necessarily surround the pixel electrode 41 in plan view. FIG. 7 is a partial plan view schematically illustrating still another example of the organic EL display device. Columns of pixel electrodes 41 are arranged in the display region 16 of the organic EL display device in a horizontal direction. The column of the pixel electrode 41 is configured by pixel electrodes 41 arranged in a vertical direction. The intermediate electrode 51 has a stripe shape, is disposed between the columns adjacent to each other, and reaches the peripheral region 17. In the peripheral region 17, the intermediate electrode 51 is connected to a wiring for supplying a potential.

In FIG. 7, a specific pixel electrode 41, a right side (left side) pixel electrode 41 adjacent to the specific pixel electrode 41 on the right side (or left side), and a lower side (upper side) pixel electrode 41 adjacent to the specific pixel electrode 41 on the lower side (or upper side) are disposed in the display region 16. In the example in FIG. 7, the intermediate electrode 51 is provided between the specific pixel electrode 41 and the right side (left side) pixel electrode 41, and the intermediate electrode 51 is not provided between the specific pixel electrode 41 and the lower side (upper side) pixel electrode 41. In this case, a region in which the intermediate electrode 51 is not provided in the bank 32 occurs. Thus, the degree of freedom of the circuit configuration is increased in comparison to the example in FIG. 3.

Here, the occurrence of slight light emission by the carriers moving from the specific pixel electrode 41 to the light emitting layer 45 on the right side (left side) pixel electrode 41 is suppressed. However, slight light emission in an adjacent pixel, which is caused by the carriers moving from the specific pixel electrode 41 to the light emitting layer 45 on the lower side (upper side) pixel electrode 41 may occur. However, for example, when the color of the unit pixel in the specific pixel electrode 41 is the same as the color of the unit pixel in the lower side (upper side) pixel electrode 41, it is possible to suppress an occurrence of electrical color mixing and is sufficiently prevent a decrease in image quality.

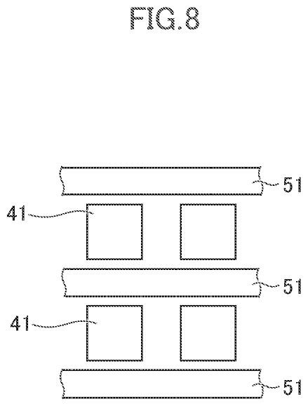

The direction of the stripe may be different from that in FIG. 7. FIG. 8 is a partial plan view schematically illustrating still another example of the organic EL display device and is a view corresponding to FIG. 7. Rows of pixel electrodes 41 are arranged in the display region 16 of the organic EL display device in the vertical direction. The row of the pixel electrode 41 is configured by pixel electrodes 41 arranged in the horizontal direction. The intermediate electrode 51 has a stripe shape and is disposed between the rows adjacent to each other. The intermediate electrode 51 is provided between the specific pixel electrode 41 and lower side (upper side) pixel electrode 41. The intermediate electrode 51 is not provided between the specific pixel electrode 41 and the right side (left side) pixel electrode 41.

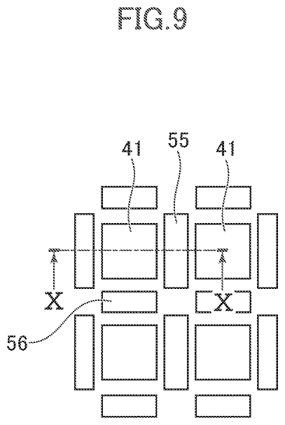

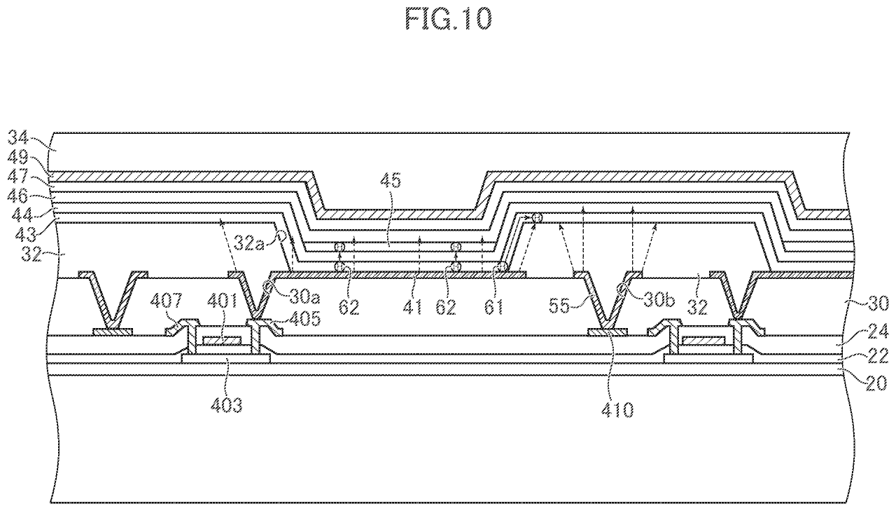

FIG. 9 is a partial plan view schematically illustrating still another example of the organic EL display device and is a view corresponding to FIG. 2. FIG. 10 is a sectional view illustrating the organic EL display device taken along line X-X illustrated in FIG. 9. Differing from the examples in FIGS. 2, 7, and 8, in the example in FIG. 9, intermediate electrodes 55 and 56 do not extend to the peripheral region 17, and a wiring 410 below the planarizing film 30 supplies a potential to the intermediate electrodes 55 and 56.

In the example in FIG. 9, in plan view, the intermediate electrode 55 is provided between the specific pixel electrode 41 and the right side (left side) pixel electrode 41, and the intermediate electrode 56 is provided between the specific pixel electrode 41 and the lower side (upper side) pixel electrode 41. The intermediate electrode 55 and the intermediate electrode 56 are spaced from each other. Therefore, there is a region in which the intermediate electrodes 55 and 56 are not provided between the specific pixel electrode 41 and the lower right (lower left, upper right, and upper left) pixel electrode 41.

Here, the planarizing film 30 has an opening 30b in a region overlapping the bank 32 in plan view. The opening 30b overlaps the intermediate electrodes 55 and 56 in plan view. The wiring 410 is exposed from the planarizing film 30, on the bottom of the opening 30b. The intermediate electrodes 55 and 56 come into contact with the wiring 410 on the bottom of the opening 30b and cover the side surface of the opening 30b and the circumference of the opening 30b in the upper surface of the planarizing film 30. Thus, it is possible to supply a potential even though the intermediate electrodes 55 and 56 do not reach the peripheral region 17. In addition, since the intermediate electrodes 55 and 56 are spaced from each other, the freedom of the layout of the electrode on the planarizing film 30 is also improved.

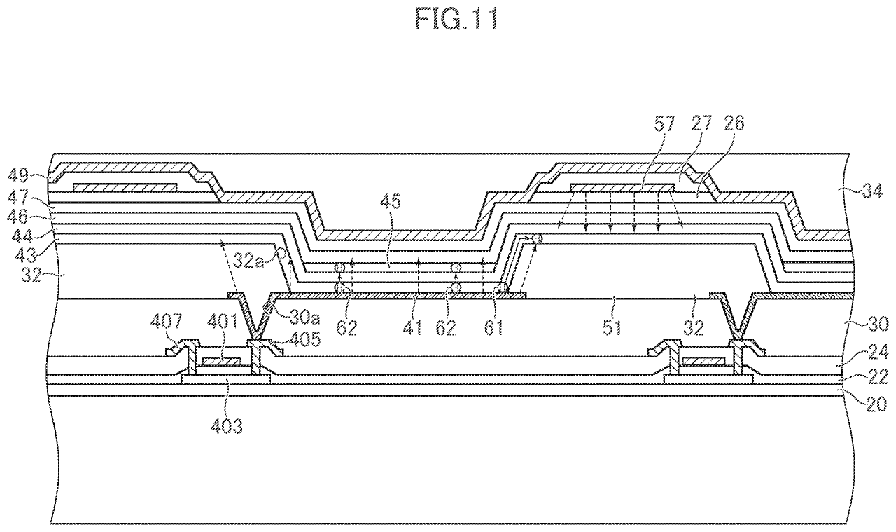

FIG. 11 is a sectional view illustrating still another example of the organic EL display device and is a view corresponding to FIG. 3. Differing from the above examples, in the example in FIG. 11, an intermediate electrode 57 is provided above the organic EL layer. More specifically, an insulating film 26 which is in contact with the upper surface of the electron injection layer 47 of the organic EL layer is formed on the bank 32, and the intermediate electrode 57 is formed on the insulating film 26. An insulating film 27 that covers the intermediate electrode 57 on the bank 32 is formed on the intermediate electrode 57. The counter electrode 49 is in contact with the insulating film 27 on the bank 32 and is in contact with the electron injection layer 47 above the opening 32a. The intermediate electrode 57 is insulated from the organic EL layer by the insulating film 26. The intermediate electrode 57 is insulated from the counter electrode 49 by the insulating film 27. When the potential of the pixel electrode 41 is higher than the potential of the counter electrode 49, the potential higher than the potential of the pixel electrode 41 is supplied to the intermediate electrode 57. An electric field from the intermediate electrode 57 toward the pixel electrode 41 in plan view is generated on the bank 32 and in at least the vicinity of the intermediate electrode 57. Thus, similar to the example in FIG. 3, it is possible to suppress moving of the hole 61 as the carrier from a certain pixel electrode 41 to the light emitting layer 45 on the adjacent pixel electrode 41 and to suppress the occurrence of slight light emission in the light emitting layer 45. Even when the potential of the pixel electrode 41 is lower than the potential of the counter electrode 49, it is possible to suppress the occurrence of slight light emission in the adjacent light emitting layer 45 by supplying the potential lower than the potential of the pixel electrode 41 to the intermediate electrode 57.

The present invention is not limited to the above-described embodiment, and various modifications can be made. For example, a replacement can be made with a configuration that is substantially the same as the configuration shown in the above-described embodiment, a configuration that exhibits the same operational effect, or a configuration that can achieve the same object.

What is claimed is:

1. A display device comprising:
a substrate;
a plurality of pixel electrodes apart from each other which are provided above the substrate;
a counter electrode disposed above the plurality of pixel electrodes;
an organic EL layer interposed between the plurality of pixel electrodes and the counter electrode;
an intermediate electrode disposed between the pixel electrodes adjacent to each other in plan view among the plurality of pixel electrodes, the intermediate electrode facing the organic EL layer; and
an insulating film provided between the intermediate electrode and the organic EL layer.

2. The display device according to claim 1, wherein
the organic EL layer includes a hole injection layer, a hole transport layer, a light emitting layer, an electron transport layer, and an electron injection layer.

3. The display device according to claim 1, wherein
a potential higher than a potential to be supplied to the counter electrode is supplied to the pixel electrode, and
a potential higher than the potential of the pixel electrode is supplied to the intermediate electrode.

4. The display device according to claim 1, further comprising:
an insulating bank provided between the pixel electrodes adjacent to each other, the insulating bank provided closer to the substrate than the organic EL layer, wherein
the intermediate electrode is provided between the insulating bank and the substrate.

5. The display device according to claim 4, further comprising:
a planarizing film between the pixel electrode and the substrate, wherein
the intermediate electrode is provided between the planarizing film and the insulating bank.

6. The display device according to claim 5, wherein
the intermediate electrode is connected to a wiring through a contact hole provided in the planarizing film.

7. The display device according to claim 4, further comprising:
an insulating protrusion portion including an upper surface and a side surface between the insulating bank and the planarizing film and between the pixel electrodes adjacent to each other, wherein
the intermediate electrode is provided between the insulating bank and at least one of the upper surface and the side surface of the insulating protrusion portion.

8. The display device according to claim 1, further comprising:
an insulating film provided between the intermediate electrode and the counter electrode, wherein
the intermediate electrode is provided between the organic EL layer and the counter electrode.

9. The display device according to claim 1, wherein
the plurality of pixel electrodes include a first pixel electrode, a second pixel electrode, and a third pixel electrode, the second pixel electrode being adjacent to the first pixel electrode in a first direction, and the third pixel electrode being adjacent to the first pixel electrode in a second direction intersecting with the first direction, and
the intermediate electrode is provided between the first pixel electrode and the second pixel electrode, but is not provided between the first pixel electrode and the third pixel electrode.

10. The display device according to claim 1, wherein
the plurality of pixel electrodes include a first pixel electrode, a second pixel electrode, and a third pixel electrode, the second pixel electrode being adjacent to the first pixel electrode in a first direction, and the third pixel electrode being adjacent to the first pixel electrode in a second direction intersecting with the first direction,
the intermediate electrode includes a first intermediate electrode provided between the first pixel electrode and the second pixel electrode and a second intermediate electrode provided between the first pixel electrode and the third pixel electrode, and
the first intermediate electrode and the second intermediate electrode are spaced from each other.

11. A display device comprising:
a substrate;
a plurality of pixels disposed on the substrate;
a plurality of pixel electrodes respectively provided in the plurality of pixels;
an organic layer located across the plurality of pixels;
a plurality of light emitting layers respectively provided in the plurality of pixels;
a counter electrode disposed above the plurality of pixel electrodes, the organic layer, and the light emitting layer;
an intermediate electrode disposed between the pixel electrodes adjacent to each other in plan view among the plurality of pixel electrodes, the intermediate electrode facing the organic layer; and
an insulating film provided between the intermediate electrode and the organic layer.

12. The display device according to claim 11, wherein
the organic layer includes a hole transport layer.

13. The display device according to claim 11, further comprising:
a bank partitioning the plurality of pixels, wherein
the insulating film includes the bank.
